(19) United States
(12) Patent Application Publication
(10) Pub. No.: US 2024/0266998 A1
(43) Pub. Date: Aug. 8, 2024

(54) PHOTOVOLTAIC MODULE, AND ASSOCIATED KIT, SYSTEM, AND METHOD

(71) Applicant: GAF Energy LLC, Parsippany, NJ (US)

(72) Inventors: Lewis Abra, San Francisco, CA (US); Henry Pham, San Jose, CA (US); Richard Perkins, San Jose, CA (US); Caleb Cheung, San Jose, CA (US); Hasib Amin, Parsippany, NJ (US)

(21) Appl. No.: 18/431,511

(22) Filed: Feb. 2, 2024

Related U.S. Application Data
(60) Provisional application No. 63/483,136, filed on Feb. 3, 2023.

(51) Int. Cl. H02S 40/36; H02S 20/23

(52) U.S. Cl. CPC H02S 40/36; H02S 20/23

(57) ABSTRACT

A photovoltaic module, including a base portion and a headlap portion, the base portion having a first layer, and at least one solar cell, the at least one solar cell above the first layer, and the first layer having an edge, headlap portion having a second layer, the second layer having an edge, the headlap portion and the base portion joined to one another along the edge of the first layer and the edge of the second layer.

### CROSS-REFERENCE TO RELATED APPLICATION

The application claims priority to U.S. provisional application No. 63/483,136, titled “PHOTOVOLTAIC MODULE, AND ASSOCIATED KIT, SYSTEM, AND METHOD,” filed Feb. 3, 2023, the disclosure of which is incorporated by reference herein in its entirety.

### FIELD OF THE INVENTION

The present disclosure relates to photovoltaic modules for a roofing deck, and, more particularly, to photovoltaic modules with a base portion and a headlap portion.

### DISCUSSION OF THE RELATED ART

Photovoltaic systems having solar panels are commonly installed on roofing structures.

### SUMMARY

The Claims, rather than the Summary, define covered embodiments of the present invention. The Summary is a high-level overview of various aspects of the invention, and introduces some of the concepts that are further described in the Detailed Description below. The Summary is not intended to identify key or essential features of the claimed subject matter, and also is not intended to be used in isolation to determine the scope of the claimed subject matter. The claimed subject matter should be understood by reference to appropriate portions of the entire Specification, any or all drawings, and each claim.

In some embodiments, the present invention provides a photovoltaic module, comprising: a base portion, wherein the base portion comprises: a first layer, and at least one solar cell, wherein the at least one solar cell is above the first layer, wherein the first layer has an edge; a headlap portion, wherein the headlap portion comprises a second layer, wherein the second layer has an edge, wherein the headlap portion and the base portion are joined to one another along the edge of the first layer and the edge of the second layer.

In some embodiments, at least one solar cell comprises a plurality of solar cells.

In some embodiments, the headlap portion further comprises at least one electrical jumper assembly, wherein the at least one electrical jumper assembly is configured to electrically connect the photovoltaic module with another photovoltaic module.

In some embodiments, the headlap portion further comprises a controller, wherein the controller is configured to control operation of the at least one solar cell.

In some embodiments, the headlap portion further comprises a communications module, wherein the communications module is configured to communicate data related to at least one of: the at least one solar cell, and a roofing deck.

In some embodiments, the headlap portion further comprises a sensor, wherein the sensor is configured to sense data related to at least one of: the at least one solar cell, and a roofing deck.

In some embodiments, the headlap portion comprises a fire-retardant material.

In some embodiments, the headlap portion further includes a fastener area, wherein the fastener area is configured to receive a fastener to hold the photovoltaic module to a roofing deck.

In some embodiments, the module further comprises a weld seam, wherein the base portion connects with the headlap portion at the weld seam.

In some embodiments, the present invention provides a kit, comprising: a base portion, wherein the base portion comprises: a first layer, and at least one solar cell, wherein the at least one solar cell is above the first layer, wherein the first layer has an edge; and a plurality of headlap portions, wherein the plurality of headlap portions comprises at least a first headlap portion, and a second headlap portion, wherein the first headlap portion comprises at least one electrical jumper assembly, wherein the at least one electrical jumper assembly is configured to electrically connect with another photovoltaic module, wherein the second headlap portion comprises a controller, wherein the controller is configured to control operation of the at least one solar cell, wherein each of the first and second headlap portions comprises a second layer, wherein each second layer has an edge, wherein the edge of each second layer is configured to join to the edge of the first layer.

In some embodiments, the at least one electrical jumper assembly is above the second layer of the first headlap portion.

In some embodiments, the plurality of headlap portions comprises a third headlap portion, wherein the third headlap portion comprises a communications module, wherein the communications module is configured to communicate data related to at least one of: the at least one solar cell, and a roofing deck.

In some embodiments, the plurality of headlap portions comprises a third headlap portion, wherein the third headlap portion comprises a sensor, wherein the sensor is configured to sense data related to at least one of: the at least one solar cell, and a roofing deck.

In some embodiments, at least one of the first headlap portion and the second headlap portion comprises a fire-retardant material.

In some embodiments, first headlap portion includes a fastener area, wherein the fastener area is configured to receive a fastener to hold the first headlap portion to a roofing deck.

In some embodiments, the edge of the first layer and the edges of the second layers are configured to be laminated with one another.

In some embodiments, the edge of the first layer and the edges of the second layers are configured to be fastened with one another.

In some embodiments, the edge of the first layer and the edges of the second layers are configured to be welded with one another.

In some embodiments, edge of the first layer and the edges of the second layers are configured to be adhered with one another.

In some embodiments, the present invention provides a photovoltaic module, comprising: a base portion, wherein the base portion comprises: a first layer, and at least one solar cell, wherein the at least one solar cell is above the first layer, wherein the base portion has: a base portion top edge, a base portion bottom edge, a base portion first side edge, and a base portion second side edge, wherein the base portion bottom edge is opposite the base portion top edge, wherein the base portion first side edge extends between the base portion top edge and the base portion bottom edge, and wherein the base portion second side edge extends between the base portion top edge and the base portion bottom edge and is opposite the base portion first side edge;

a headlap portion, wherein the headlap portion comprises: a second layer, wherein the headlap portion has: a headlap portion top edge, a headlap portion bottom edge, a headlap portion first side edge, and a headlap portion second side edge, wherein the headlap portion bottom edge is opposite the headlap portion top edge, wherein the headlap portion first side edge extends between the headlap portion top edge and the headlap portion bottom edge, and wherein the headlap portion second side edge extends between the headlap portion top edge and the headlap portion bottom edge and is opposite the headlap portion first side edge, wherein an entire length of the base portion top edge and an entire length of the headlap portion bottom edge connect with each another.

In some embodiments, the at least one solar cell comprises a plurality of solar cells, wherein the plurality of solar cells are adjacent one another near the base portion bottom edge and between the base portion first side edge and the base portion second side edge.

In some embodiments, the headlap portion further comprises: at least one electrical jumper assembly, wherein the at least one electrical jumper assembly is configured to electrically connect the at least one solar cell with at least one solar cell of another photovoltaic module.

In some embodiments, the headlap portion further comprises: at least one electrical jumper assembly, wherein the at least one electrical jumper assembly is configured to electrically connect the photovoltaic module with another photovoltaic module.

In some embodiments, the headlap portion further comprises: at least one jumper sleeve, wherein the at least one jumper sleeve is above the second layer.

In some embodiments, the headlap portion further comprises: a controller, wherein the controller is configured to control operation of the at least one solar cell.

In some embodiments, the headlap portion further comprises: a communications module, wherein the communications module is configured to communicate data related to at least one of: the at least one solar cell, and a roofing deck.

In some embodiments, the headlap portion further comprises: a sensor, wherein the sensor is configured to sense data related to at least one of: the at least one solar cell, and a roofing deck.

In some embodiments, the headlap portion comprises a fire-retardant material.

In some embodiments, the headlap portion further includes a fastener area, wherein the fastener area is configured to receive a fastener to hold the photovoltaic module to a roofing deck.

In some embodiments, the photovoltaic module further comprises: a weld seam, wherein the base portion connects with the headlap portion at the weld seam, wherein the weld seam extends the entire length of the base portion top edge and the entire length of the headlap portion bottom edge.

In some embodiments, the present invention provides a kit, comprising: a base portion, wherein the base portion comprises: a first layer, and at least one solar cell, wherein the at least one solar cell is above the first layer, wherein the base portion has: a base portion top edge, a base portion bottom edge, a base portion first side edge, and a base portion second side edge, wherein the base portion bottom edge is opposite the base portion top edge, wherein the base portion first side edge extends between the base portion top edge and the base portion bottom edge, and wherein the base portion second side edge extends between the base portion top edge and the base portion bottom edge and is opposite the base portion first side edge; a plurality of headlap portions, wherein the plurality of headlap portions comprises at least: a first headlap portion, and a second headlap portion, wherein each of the first and second headlap portions comprises: a second layer, wherein each of the first and second headlap portions has: a headlap portion top edge, a headlap portion bottom edge, a headlap portion first side edge, and a headlap portion second side edge, wherein the headlap portion bottom edge is opposite the headlap portion top edge, wherein the headlap portion first side edge extends between the headlap portion top edge and the headlap portion bottom edge, and wherein the headlap portion second side edge extends between the headlap portion top edge and the headlap portion bottom edge and is opposite the headlap portion first side edge; and, wherein the headlap portion bottom edge of the first headlap portion and the base portion top edge are connectable with one another, wherein the headlap portion bottom edge of the second headlap portion and the base portion top edge are connectable with one another, wherein the first headlap portion comprises: at least one electrical jumper assembly, wherein the at least one electrical jumper assembly is configured to electrically connect with another photovoltaic module, and wherein the second headlap portion comprises: a controller, wherein the controller is configured to control operation of the at least one solar cell.

In some embodiments, the plurality of headlap portions comprises: a third headlap portion, wherein the third headlap portion comprises: a communications module, wherein the communications module is configured to communicate data related to at least one of: the at least one solar cell, and a roofing deck.

In some embodiments, the plurality of headlap portions comprises: a third headlap portion, wherein the third headlap portion comprises: a sensor, wherein the sensor is configured to sense data related to at least one of: the at least one solar cell, and a roofing deck.

In some embodiments, the bottom edge of the first headlap portion and the top edge of the base portion are configured to be laminated with one another.

In some embodiments, the bottom edge of the first headlap portion and the top edge of the base portion are configured to be fastened with one another.

In some embodiments, the bottom edge of the first headlap portion and the top edge of the base portion are configured to be welded with one another.

In some embodiments, the bottom edge of the first headlap portion and the top edge of the base portion are configured to be adhered with one another.

In some embodiments, the present invention provides a method, comprising: obtaining a base portion, wherein the base portion comprises: a first layer, and at least one solar cell, wherein the at least one solar cell is above the first layer, wherein the base portion has: a base portion top edge, a base portion bottom edge, a base portion first side edge, and a base portion second side edge, wherein the base portion bottom edge is opposite the base portion top edge, wherein the base portion first side edge extends between the base portion top edge and the base portion bottom edge, and wherein the base portion second side edge extends between the base portion top edge and the base portion bottom edge and is opposite the base portion first side edge; obtaining a headlap portion, wherein the headlap portion comprises: a second layer, wherein the headlap portion has: a headlap portion top edge, a headlap portion bottom edge, a headlap portion first side edge, and a headlap portion second side edge, wherein the headlap portion bottom edge is opposite the headlap portion top edge, wherein the headlap portion first side edge extends between the headlap portion top edge and the headlap portion bottom edge, and wherein the headlap portion second side edge extends between the headlap portion top edge and the headlap portion bottom edge and is opposite the headlap portion first side edge; and connecting an entire length of the base portion top edge and an entire length of the headlap portion top edge to one another, thereby to form a photovoltaic module.

In some embodiments, connecting comprises laminating the entire length of the base portion top edge and the entire length of the headlap portion top edge to one another.

In some embodiments, connecting comprises fastening the entire length of the base portion top edge and the entire length of the headlap portion top edge to one another.

In some embodiments, connecting comprises welding the entire length of the base portion top edge and the entire length of the headlap portion top edge to one another.

In some embodiments, connecting comprises adhering the entire length of the base portion top edge and the entire length of the headlap portion top edge to one another.

In some embodiments, connecting comprises welding the top edge of the base portion with the bottom edge of the headlap portion bottom edge, to form a weld seam, wherein the weld seam extends the entire length of the base portion top edge and the entire length of the headlap portion top edge.

In some embodiments, the present invention provides a roofing system, comprising: a roofing deck; and a photovoltaic module installed above the roofing deck, wherein the photovoltaic module comprises: a base portion, wherein the base portion comprises: a first layer, and at least one solar cell, wherein the at least one solar cell is above the first layer, wherein the base portion has: a base portion top edge, a base portion bottom edge, a base portion first side edge, and a base portion second side edge, wherein the base portion bottom edge is opposite the base portion top edge, wherein the base portion first side edge extends between the base portion top edge and the base portion bottom edge, and wherein the base portion second side edge extends between the base portion top edge and the base portion bottom edge and is opposite the base portion first side edge; a headlap portion, wherein the headlap portion comprises: a second layer, wherein the headlap portion has: a headlap portion top edge, a headlap portion bottom edge, a headlap portion first side edge, and a headlap portion second side edge, wherein the headlap portion bottom edge is opposite the headlap portion top edge, wherein the headlap portion first side edge extends between the headlap portion top edge and the headlap portion bottom edge, and wherein the headlap portion second side edge extends between the headlap portion top edge and the headlap portion bottom edge and is opposite the headlap portion first side edge, wherein an entire length of the base portion top edge and an entire length of the headlap portion bottom edge connect with each another.

### BRIEF DESCRIPTION OF THE DRAWINGS

This section refers to the drawings that form a part of this disclosure, and which illustrate embodiments of materials and methods described herein.

FIG. 1 is an top view of an embodiment of a photovoltaic module, in accordance with some embodiments of the present invention.

FIG. 2 is a top view of a base portion of a photovoltaic module, in accordance with some embodiments of the invention.

FIG. 3 is a top view of a headlap portion of a photovoltaic module, in accordance with some embodiments of the invention.

FIG. 4 is a top view of a headlap portion of a photovoltaic module, in accordance with some embodiments of the invention.

### DETAILED DESCRIPTION

In addition to the benefits and improvements that the Specification discloses, other objects and advantages of that the Specification provides will become apparent from the following description taken in conjunction with the accompanying figures. Although the description discloses and describes detailed embodiments of the present disclosure, the disclosed embodiments are merely illustrative of the disclosure that may be embodied in various forms. In addition, each of the examples given regarding the various embodiments of the disclosure are intended to be illustrative, and not restrictive.

Throughout the specification and claims, the following terms take the meanings explicitly associated herein, unless the context clearly dictates otherwise. The phrases “in an embodiment,” “in some embodiments,” and any similar phrase, as used herein, do not necessarily refer to the same embodiment or embodiments, though the phrases may refer to the same embodiment or embodiments. Furthermore, the phrases “in another embodiment,” and any similar phrase, as used herein, do not necessarily refer to a different embodiment, although the phrases may refer to a different embodiment. All embodiments of the disclosure are intended to be combinable without departing from the scope or spirit of the disclosure.

As used herein, terms such as “comprising,” “including,” “having,” and any similar phrase, do not limit the scope of a specific claim to the materials or steps recited by the claim.

As used herein, a “steep slope roof” is a roof that is disposed on a building, such as a house or other residential structure, having a pitch of Y/X, where Y and X are in a ratio of 4:12 to 20:12, where Y corresponds to the “rise” of the roof, and where X corresponds to the “run” of the roof.

In some embodiments, the present invention provides a photovoltaic module with a base portion and a headlap portion, where the base portion and the headlap portion are joinable with one another.

In some embodiments, the present invention provides a photovoltaic module with a base portion and a headlap portion, where the base portion and the headlap portion are connectable with one another.

In some embodiments, the photovoltaic module is installed on a roof. In some embodiments, the photovoltaic module is installed on a steep slope roof. In some embodiments, the photovoltaic module is installed on sloped roof that has a slope less than that of a steep sloped roof.

In some embodiments, the base portion comprises a first layer. In some embodiments, the first layer may be composed of a polymer. In some embodiments, the first layer may be composed of thermoplastic polyolefin (TPO). In some embodiments, the first layer may be composed of polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), or polyimide; polyvinyl chloride (PVC); ethylene propylene diene monomer (EPDM) rubber; silicone rubber; fluoropolymers such as ethylene tetrafluoroethylene (ETFE), polyvinylidene fluoride (PVDF), tetrafluoroethylene-hexafluoropropylene copolymers (FEP), and/or tetrafluoroethylene-hexafluoropropylene-vinylidene fluoride copolymers (THV), or blends thereof.

In some embodiments, the base portion comprises at least one solar cell, In some embodiments, the at least one solar cell comprises two solar cells. In some embodiments, the at least one solar cell comprises three solar cells. In some embodiments, the at least one solar cell comprises four solar cells. In some embodiments, the at least one solar cell comprises five solar cells. In some embodiments, the at least one solar cell comprises six solar cells. In some embodiments, the at least one solar cell comprises seven solar cells. In some embodiments, the at least one solar cell comprises eight solar cells. In some embodiments, the at least one solar cell comprises more than eight solar cells.

In some embodiments, the at least one solar cell comprises a plurality of groups of solar cells. In some embodiments, each of the plurality of groups of solar cells includes a plurality of solar cells.

In some embodiments, the at least one solar cell is above the first layer. In some embodiments, the at least one solar cell is directly above the first layer—that is, there is no intervening layer between the at least one solar cell and the first layer. In some embodiments, at least one solar cell is not directly above the first layer—that is, there is at least one layer intervening between the at least one solar cell and the first layer. In some embodiments, there is at least two layers intervening between the at least one solar cell and the first layer. In some embodiments, there is at three layers intervening between the at least one solar cell and the first layer. In some embodiments, there are more than three layers intervening between the at least one solar cell and the first layer.

In some embodiments, the at least one solar cell is connected to the first layer. In some embodiments, the at least one solar cell is adhered to the first layer. In some embodiments, the at least one solar cell is laminated to the first layer. In some embodiments, the at least one solar cell is fastened (such as by one or more of a chemical and/or mechanical fastener) to the first layer.

In some embodiments, the base portion includes at least one junction box. In some embodiments, the junction box is electrically connected to at least one electrical bussing of the photovoltaic module. In some embodiments, the junction box is electrically connected to at least one electrical bussing of the photovoltaic module. In some embodiments, the base portion includes two junction boxes. In some embodiments, the base portion includes more than two junction boxes. In some embodiments, the base portion omits the junction box.

In some embodiments, the base portion has a base portion top edge, a base portion bottom edge, a base portion first side edge, and a base portion second side edge, wherein the base portion bottom edge is opposite the base portion top edge, wherein the base portion first side edge extends between the base portion top edge and the base portion bottom edge, and wherein the base portion second side edge extends between the base portion top edge and the base portion bottom edge and is opposite the base portion first side edge.

In some embodiments, the at least one solar cell comprises a plurality of solar cells, and the plurality of solar cells are adjacent one another near the base portion bottom edge and between the base portion first side edge and the base portion second side edge.

In some embodiments, the headlap portion comprises a second layer. In some embodiments, the second layer may be composed of a polymer. In some embodiments, the second layer may be composed of thermoplastic polyolefin (TPO). In some embodiments, the second layer may be composed of polyethylene terephthalate (PET), polyethylene naphthalate (PEN), polyetheretherketone (PEEK), polyaryletherketone (PAEK), polyarylate (PAR), polyetherimide (PEI), polyarylsulfone (PAS), polyethersulfone (PES), polyamideimide (PAI), or polyimide; polyvinyl chloride (PVC); ethylene propylene diene monomer (EPDM) rubber; silicone rubber; fluoropolymers such as ethylene tetrafluoroethylene (ETFE), polyvinylidene fluoride (PVDF), tetrafluoroethylene-hexafluoropropylene copolymers (FEP), and/or tetrafluoroethylene-hexafluoropropylene-vinylidene fluoride copolymers (THV), or blends thereof. In some embodiments, a material of the second layer is the same as the material of the first layer. In some embodiments, a material of the second layer is different that the material of the first layer.

In some embodiments, either or both of the base portion and/or the headlap portion has a thickness from 5 mm to 20 mm. In some embodiments, either or both of the base portion and/or the headlap portion has a thickness from 6 mm to 20 mm. In some embodiments, either or both of the base portion and/or the headlap portion has a thickness from 7 mm to 20 mm. In some embodiments, either or both of the base portion and/or the headlap portion has a thickness from 8 mm to 20 mm. In some embodiments, either or both of the base portion and/or the headlap portion has a thickness from 9 mm to 20 mm. In some embodiments, either or both of the base portion and/or the headlap portion has a thickness from 10 mm to 20 mm. In some embodiments, either or both of the base portion and/or the headlap portion has a thickness from 11 mm to 20 mm. In some embodiments, either or both of the base portion and/or the headlap portion has a thickness from 12 mm to 20 mm. In some embodiments, either or both of the base portion and/or the headlap portion has a thickness from 13 mm to 20 mm. In some embodiments, either or both of the base portion and/or the headlap portion has a thickness from 14 mm to 20 mm. In some embodiments, either or both of the base portion and/or the headlap portion has a thickness from 15 mm to 20 mm. In some embodiments, either or both of the base portion and/or the headlap portion has a thickness from 16 mm to 20 mm. In some embodiments, either or both of the base portion and/or the headlap portion has a thickness from 17 mm to 20 mm. In some embodiments, either or both of the base portion and/or the headlap portion has a thickness from 18 mm to 20 mm. In some embodiments, either or both of the base portion and/or the headlap portion has a thickness from 19 mm to 20 mm.

In some embodiments, either or both of the base portion and/or the headlap portion has a thickness from 5 mm to 19 mm. In some embodiments, either or both of the base portion and/or the headlap portion has a thickness from 6 mm to 19 mm. In some embodiments, either or both of the base portion and/or the headlap portion has a thickness from 7 mm to 19 mm. In some embodiments, either or both of the base portion and/or the headlap portion has a thickness from 8 mm to 19 mm. In some embodiments, either or both of the base portion and/or the headlap portion has a thickness from 9 mm to 19 mm. In some embodiments, either or both of the base portion and/or the headlap portion has a thickness from 10 mm to 19 mm. In some embodiments, either or both of the base portion and/or the headlap portion has a thickness from 11 mm to 19 mm. In some embodiments, either or both of the base portion and/or the headlap portion has a thickness from 12 mm to 19 mm. In some embodiments, either or both of the base portion and/or the headlap portion has a thickness from 13 mm to 19 mm. In some embodiments, either or both of the base portion and/or the headlap portion has a thickness from 14 mm to 19 mm. In some embodiments, either or both of the base portion and/or the headlap portion has a thickness from 15 mm to 19 mm. In some embodiments, either or both of the base portion and/or the headlap portion has a thickness from 16 mm to 19 mm. In some embodiments, either or both of the base portion and/or the headlap portion has a thickness from 17 mm to 19 mm. In some embodiments, either or both of the base portion and/or the headlap portion has a thickness from 18 mm to 19 mm.

In some embodiments, either or both of the base portion and/or the headlap portion has a thickness from 5 mm to 18 mm. In some embodiments, either or both of the base portion and/or the headlap portion has a thickness from 6 mm to 18 mm. In some embodiments, either or both of the base portion and/or the headlap portion has a thickness from 7 mm to 18 mm. In some embodiments, either or both of the base portion and/or the headlap portion has a thickness from 8 mm to 18 mm. In some embodiments, either or both of the base portion and/or the headlap portion has a thickness from 9 mm to 18 mm. In some embodiments, either or both of the base portion and/or the headlap portion has a thickness from 10 mm to 18 mm. In some embodiments, either or both of the base portion and/or the headlap portion has a thickness from 11 mm to 18 mm. In some embodiments, either or both of the base portion and/or the headlap portion has a thickness from 12 mm to 18 mm. In some embodiments, either or both of the base portion and/or the headlap portion has a thickness from 13 mm to 18 mm. In some embodiments, either or both of the base portion and/or the headlap portion has a thickness from 14 mm to 18 mm. In some embodiments, either or both of the base portion and/or the headlap portion has a thickness from 15 mm to 18 mm. In some embodiments, either or both of the base portion and/or the headlap portion has a thickness from 16 mm to 18 mm. In some embodiments, either or both of the base portion and/or the headlap portion has a thickness from 17 mm to 18 mm.

In some embodiments, either or both of the base portion and/or the headlap portion has a thickness from 5 mm to 17 mm. In some embodiments, either or both of the base portion and/or the headlap portion has a thickness from 6 mm to 17 mm. In some embodiments, either or both of the base portion and/or the headlap portion has a thickness from 7 mm to 17 mm. In some embodiments, either or both of the base portion and/or the headlap portion has a thickness from 8 mm to 17 mm. In some embodiments, either or both of the base portion and/or the headlap portion has a thickness from 9 mm to 17 mm. In some embodiments, either or both of the base portion and/or the headlap portion has a thickness from 10 mm to 17 mm. In some embodiments, either or both of the base portion and/or the headlap portion has a thickness from 11 mm to 17 mm. In some embodiments, either or both of the base portion and/or the headlap portion has a thickness from 12 mm to 17 mm. In some embodiments, either or both of the base portion and/or the headlap portion has a thickness from 13 mm to 17 mm. In some embodiments, either or both of the base portion and/or the headlap portion has a thickness from 14 mm to 17 mm. In some embodiments, either or both of the base portion and/or the headlap portion has a thickness from 15 mm to 17 mm. In some embodiments, either or both of the base portion and/or the headlap portion has a thickness from 16 mm to 17 mm.

In some embodiments, either or both of the base portion and/or the headlap portion has a thickness from 5 mm to 16 mm. In some embodiments, either or both of the base portion and/or the headlap portion has a thickness from 6 mm to 16 mm. In some embodiments, either or both of the base portion and/or the headlap portion has a thickness from 7 mm to 16 mm. In some embodiments, either or both of the base portion and/or the headlap portion has a thickness from 8 mm to 16 mm. In some embodiments, either or both of the base portion and/or the headlap portion has a thickness from 9 mm to 16 mm. In some embodiments, either or both of the base portion and/or the headlap portion has a thickness from 10 mm to 16 mm. In some embodiments, either or both of the base portion and/or the headlap portion has a thickness from 11 mm to 16 mm. In some embodiments, either or both of the base portion and/or the headlap portion has a thickness from 12 mm to 16 mm. In some embodiments, either or both of the base portion and/or the headlap portion has a thickness from 13 mm to 16 mm. In some embodiments, either or both of the base portion and/or the headlap portion has a thickness from 14 mm to 16 mm. In some embodiments, either or both of the base portion and/or the headlap portion has a thickness from 15 mm to 16 mm.

In some embodiments, either or both of the base portion and/or the headlap portion has a thickness from 5 mm to 15 mm. In some embodiments, either or both of the base portion and/or the headlap portion has a thickness from 6 mm to 15 mm. In some embodiments, either or both of the base portion and/or the headlap portion has a thickness from 7 mm to 15 mm. In some embodiments, either or both of the base portion and/or the headlap portion has a thickness from 8 mm to 15 mm. In some embodiments, either or both of the base portion and/or the headlap portion has a thickness from 9 mm to 15 mm. In some embodiments, either or both of the base portion and/or the headlap portion has a thickness from 10 mm to 15 mm. In some embodiments, either or both of the base portion and/or the headlap portion has a thickness from 11 mm to 15 mm. In some embodiments, either or both of the base portion and/or the headlap portion has a thickness from 12 mm to 15 mm. In some embodiments, either or both of the base portion and/or the headlap portion has a thickness from 13 mm to 15 mm. In some embodiments, either or both of the base portion and/or the headlap portion has a thickness from 14 mm to 15 mm.

In some embodiments, either or both of the base portion and/or the headlap portion has a thickness from 5 mm to 14 mm. In some embodiments, either or both of the base portion and/or the headlap portion has a thickness from 6 mm to 14 mm. In some embodiments, either or both of the base portion and/or the headlap portion has a thickness from 7 mm to 14 mm. In some embodiments, either or both of the base portion and/or the headlap portion has a thickness from 8 mm to 14 mm. In some embodiments, either or both of the base portion and/or the headlap portion has a thickness from 9 mm to 14 mm. In some embodiments, either or both of the base portion and/or the headlap portion has a thickness from 10 mm to 14 mm. In some embodiments, either or both of the base portion and/or the headlap portion has a thickness from 11 mm to 14 mm. In some embodiments, either or both of the base portion and/or the headlap portion has a thickness from 12 mm to 14 mm. In some embodiments, either or both of the base portion and/or the headlap portion has a thickness from 13 mm to 14 mm.

In some embodiments, either or both of the base portion and/or the headlap portion has a thickness from 5 mm to 13 mm. In some embodiments, either or both of the base portion and/or the headlap portion has a thickness from 6 mm to 13 mm. In some embodiments, either or both of the base portion and/or the headlap portion has a thickness from 7 mm to 13 mm. In some embodiments, either or both of the base portion and/or the headlap portion has a thickness from 8 mm to 13 mm. In some embodiments, either or both of the base portion and/or the headlap portion has a thickness from 9 mm to 13 mm. In some embodiments, either or both of the base portion and/or the headlap portion has a thickness from 10 mm to 13 mm. In some embodiments, either or both of the base portion and/or the headlap portion has a thickness from 11 mm to 13 mm. In some embodiments, either or both of the base portion and/or the headlap portion has a thickness from 12 mm to 13 mm.

In some embodiments, either or both of the base portion and/or the headlap portion has a thickness from 5 mm to 12 mm. In some embodiments, either or both of the base portion and/or the headlap portion has a thickness from 6 mm to 12 mm. In some embodiments, either or both of the base portion and/or the headlap portion has a thickness from 7 mm to 12 mm. In some embodiments, either or both of the base portion and/or the headlap portion has a thickness from 8 mm to 12 mm. In some embodiments, either or both of the base portion and/or the headlap portion has a thickness from 9 mm to 12 mm. In some embodiments, either or both of the base portion and/or the headlap portion has a thickness from 10 mm to 12 mm. In some embodiments, either or both of the base portion and/or the headlap portion has a thickness from 11 mm to 12 mm.

In some embodiments, either or both of the base portion and/or the headlap portion has a thickness from 5 mm to 11 mm. In some embodiments, either or both of the base portion and/or the headlap portion has a thickness from 6 mm to 11 mm. In some embodiments, either or both of the base portion and/or the headlap portion has a thickness from 7 mm to 11 mm. In some embodiments, either or both of the base portion and/or the headlap portion has a thickness from 8 mm to 11 mm. In some embodiments, either or both of the base portion and/or the headlap portion has a thickness from 9 mm to 11 mm. In some embodiments, either or both of the base portion and/or the headlap portion has a thickness from 10 mm to 11 mm.

In some embodiments, either or both of the base portion and/or the headlap portion has a thickness from 5 mm to 10 mm. In some embodiments, either or both of the base portion and/or the headlap portion has a thickness from 6 mm to 10 mm. In some embodiments, either or both of the base portion and/or the headlap portion has a thickness from 7 mm to 10 mm. In some embodiments, either or both of the base portion and/or the headlap portion has a thickness from 8 mm to 10 mm. In some embodiments, either or both of the base portion and/or the headlap portion has a thickness from 9 mm to 10 mm.

In some embodiments, either or both of the base portion and/or the headlap portion has a thickness from 5 mm to 9 mm. In some embodiments, either or both of the base portion and/or the headlap portion has a thickness from 6 mm to 9 mm. In some embodiments, either or both of the base portion and/or the headlap portion has a thickness from 7 mm to 9 mm. In some embodiments, either or both of the base portion and/or the headlap portion has a thickness from 8 mm to 9 mm.

In some embodiments, either or both of the base portion and/or the headlap portion has a thickness from 5 mm to 8 mm. In some embodiments, either or both of the base portion and/or the headlap portion has a thickness from 6 mm to 8 mm. In some embodiments, either or both of the base portion and/or the headlap portion has a thickness from 7 mm to 8 mm. In some embodiments, either or both of the base portion and/or the headlap portion has a thickness from 5 mm to 7 mm. In some embodiments, either or both of the base portion and/or the headlap portion has a thickness from 6 mm to 7 mm. In some embodiments, either or both of the base portion and/or the headlap portion has a thickness from 5 mm to 6 mm.

In some embodiments, the thickness of the base portion is the same as the thickness of the headlap portion. In some embodiments, the thickness of the base portion is different than the thickness of the headlap portion.

In some embodiments, the headlap portion has a headlap portion top edge, a headlap portion bottom edge, a headlap portion first side edge, and a headlap portion second side edge, wherein the headlap portion bottom edge is opposite the headlap portion top edge, where the headlap portion first side edge extends between the headlap portion top edge and the headlap portion bottom edge, and where the headlap portion second side edge extends between the headlap portion top edge and the headlap portion bottom edge and is opposite the headlap portion first side edge.

In some embodiments, the base portion top edge and the headlap portion bottom edge connect with each another. In some embodiments, an entire length of the base portion top edge and an entire length of the headlap portion bottom edge connect with each another. In some embodiments, less than the entire length of the base portion top edge and the entire length of the headlap portion bottom edge connect with each another. In some embodiments, the entire length of the base portion top edge is connected to less than the entire length of the headlap portion bottom edge. In some embodiments, less than the entire length of the base portion top edge is connected to the entire length of the headlap portion bottom edge.

In some embodiments, the photovoltaic module may have a structure, function, composition and/or components in one or more embodiments discloses in U.S. Pat. No. 11,404,997, titled “Photovoltaic Shingles and Methods of Installing Same,” issued Aug. 2, 2022; U.S. Pat. No. 11,251,744, titled “Photovoltaic Shingles and Methods of Installing Same,” issued Feb. 15, 2022; and PCT International Patent Publication No. WO 2022/051593, Application No. PCT/US2021/049017, published Mar. 10, 2022, titled “Building Integrated Photovoltaic System,” all of the foregoing owned by GAF Energy LLC, and the disclosures of each of the foregoing patent properties are incorporated by reference herein in their entireties.

In some embodiments, the headlap portion further comprises at least one electrical jumper assembly. In some embodiments, the at least one electrical jumper assembly is configured to electrically connect the at least one solar cell with at least one solar cell of another photovoltaic module. In some embodiments, the at least one electrical jumper assembly is configured to electrically connect the photovoltaic module with another photovoltaic module. In some embodiments, the electrical jumper assembly may be one or more embodiments of the electrical jumper assembly set forth in U.S. patent application Ser. No. 18/475,891, filed Sep. 27, 2023, titled “JUMPER MODULE WITH SLEEVE,” the disclosure of which is incorporated by reference herein in its entirety.

In some embodiments, the headlap portion further comprises at least one jumper sleeve, wherein the at least one jumper sleeve is above the second layer. In some embodiments, the at least one jumper sleeve is above the second layer. In some embodiments, the at least one jumper sleeve is directly above the second layer—that is, there is no intervening layer between the at least one jumper sleeve and the second layer. In some embodiments, at least one jumper sleeve is not directly above the second layer—that is, there is at least one layer intervening between the at least one jumper sleeve and the second layer. In some embodiments, there is at least two layers intervening between the at least one jumper sleeve and the second layer. In some embodiments, there is at least three layers intervening between the at least one jumper sleeve and the second layer. In some embodiments, there are more than three layers intervening between the at least one jumper sleeve and the second layer. In some embodiments, the jumper sleeve may be connected to the headlap portion by a fastener, an adhesive, welding, or laminating. In some embodiments, the jumper sleeve may be one or more embodiments of the jumper sleeve set forth in U.S. patent application Ser. No. 18/475,891, filed Sep. 27, 2023, titled “JUMPER MODULE WITH SLEEVE,” the disclosure of which is incorporated by reference herein in its entirety.

In some embodiments, the headlap portion further comprises a controller. In some embodiments, the controller is configured to control operation of the at least one solar cell. In some embodiments, the controller is configured to control operation of an electronic component other than the at least one solar cell. In some embodiments, the controller is configured to control operation of an electronic component other than the at least one solar cell, as well as the at least one solar cell.

In some embodiments, the headlap portion further comprises a communications module. In some embodiments, the communications module is configured to communicate data related to at least one of the at least one solar cell, and a roofing deck. In some embodiments, the communications module is configured to communicate data related to both of the at least one solar cell and the roofing deck. In some embodiments, the communications module is configured to communicate data related to one or more components other than at least one of the at least one solar cell, and/or the roofing deck.

In some embodiments, the headlap portion further comprises a sensor. In some embodiments, the sensor is configured to sense data related to at least one of the at least one solar cell, and a roofing deck. In some embodiments, the sensor is configured to sense data related to both of the at least one solar cell, and the roofing deck. In some embodiments, the sensor is configured to sense data related to something other than the at least one solar cell, and/or the roofing deck.

In some embodiments, either or both of the headlap portion and/or the base portion comprises one or more other components or modules. By way of non-limiting examples, such components may but need not, include one or more of a rapid shut down module or component, embedded power electronics module or component, DC optimizer module or component, microinverter module or component, wireless power transmitter module or component, voltage sensor module or component, current sensor module or component, temperature sensor module or component, humidity sensor module or component, communication hardware sensor module or component, RFID sensor module or component, Wi-Fi sensor module or component, and/or 5G sensor module or component.

In some embodiments, the headlap portion comprises a fire-resistant or fire-retardant material. In some embodiments, the fire-retardant headlap portion includes one or more of, or all of, or none of, a jumper module, an electrical jumper assembly, a jumper sleeve, a controller, a communications module, a sensor, and/or another electronic and/or nonelectronic component.

In some embodiments, the headlap portion is composed of a material that imparts any or all of the following characteristics: increased thermal insulation, increased thermal conductivity, increased mechanical strength (such as, for example, for higher wind resistance), and/or increased infrared (IR) reflectivity. In some embodiments, the headlap portion material may be chosen to provide a photovoltaic module that meets jurisdiction or other standards or requirements.

In some embodiments, wherein the headlap portion further includes a fastener area (i.e., “nail zone”). In some embodiments, the fastener area is configured to receive a fastener to hold the photovoltaic module to the roofing deck. In some embodiments, the fastener area is configured to receive a plurality of fasteners to hold the photovoltaic module to the roofing deck. In some embodiments, the headlap portion omits a fastener area. In some embodiments, the fastener area is configured to receive one or more of any of, or each of, a nail, staple, screw, and/or rivet. Thus, in some embodiments, when the photovoltaics module is installed on a roofing deck, the fastener area receive one or more of any of, or each of, a nail, staple, screw, and/or rivet, thereby to install the photovoltaic module on the roofing deck.

In some embodiments, the fastener area may be on a portion of the headlap portion only, the base portion only, or both the headlap portion as well as the base portion.

As discussed, in some embodiments, the headlap portion is connected with the base portion. In some embodiments, the headlap portion and base portion are connected in a manufacturing facility. In some embodiments, the headlap portion and base portion are connected in a manufacturing facility after formation of the headlap portion and the base portion. In some embodiments, the headlap portion and base portion are connected outside a manufacturing facility. In some embodiments, the headlap portion and base portion are connected at a job site—for example, on the roofing deck, such as prior to installation of the photovoltaic module, the base portion, and/or the headlap portion to the roofing deck; and/or at a location adjacent to the roofing deck.

In some embodiments, the photovoltaic module includes the base portion and the headlap portion that are adhered to one another. In some embodiments, the photovoltaic module includes the base portion and the headlap portion that are laminated to one another. In some embodiments, the photovoltaic module includes the base portion and the headlap portion that are fastened (such as by one or more of a chemical and/or mechanical fastener) to one another. In some embodiments, the photovoltaic module includes the base portion and the headlap portion that are welded (such as by ultrasonic welding, or heat welding, for example) to one another.

In some embodiments, the base portion is welded to the headlap portion, to form a weld seam. In some embodiments, the weld seam extends the entire length of the base portion top edge and the entire length of the headlap portion top edge. In some embodiments, the weld seam extends less than the entire length of the base portion top edge and less than the entire length of the headlap portion top edge.

In some embodiments, a kit includes one or more base portions, and/or one or more headlap portions, which are connectable to one another, but which may or not be connected to one another. In some embodiments, the headlap portion and the base portion are configured to be adhered, laminated, fastened, and/or welded to one another, but may or may not be connected.

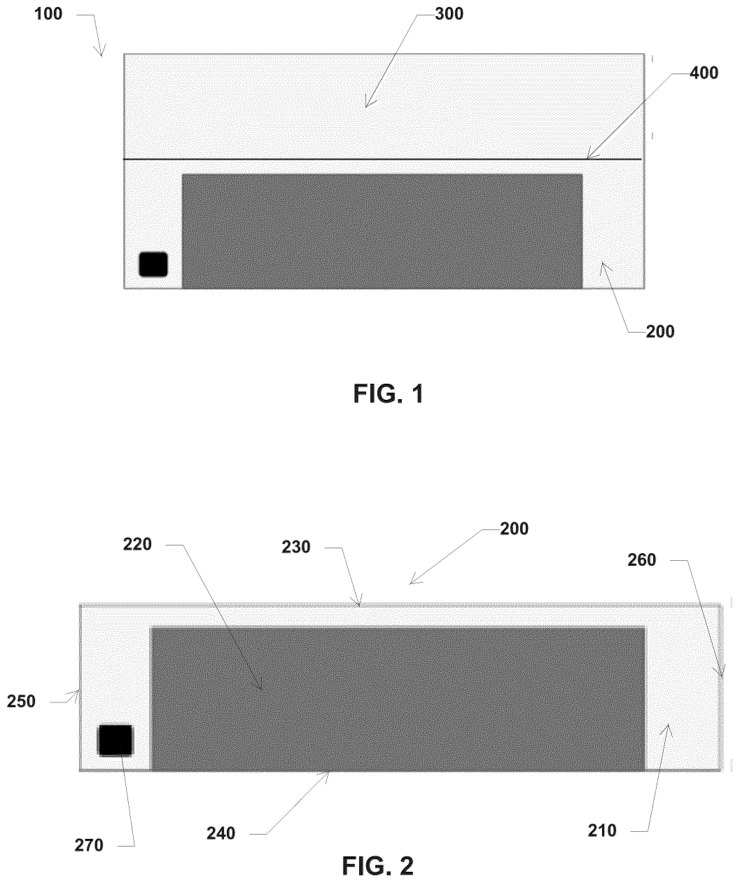

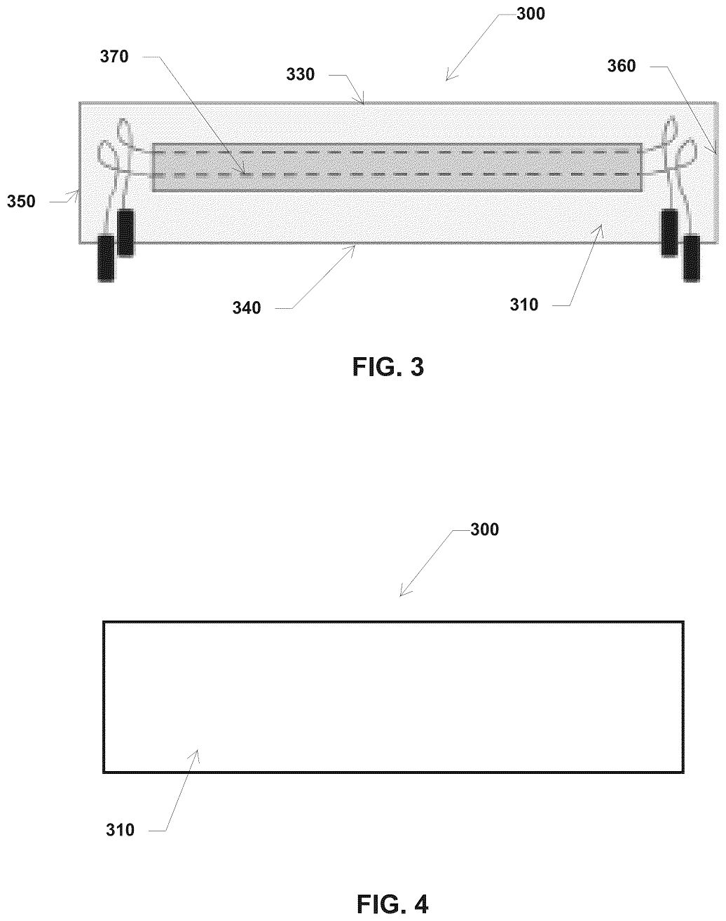

FIG. 1 is an top view of an embodiment of a photovoltaic module 100, in accordance with some embodiments of the present invention. As FIG. 1 shows, the photovoltaic module 100 includes a base portion 200 and a headlap portion 300. FIG. 2 is a top view of the base portion 200 of the photovoltaic module 100, in accordance with some embodiments of the invention. FIGS. 3 and 4 are top views of the headlap portion 300 of the photovoltaic module 100, in accordance with some embodiments of the invention. As the figures show, and in accordance with the discussion herein, the base portion 200 may include a first layer 210. In some embodiments, the base portion 200 may include at least one solar cell 220. The at least one solar cell 220 may be above the first layer 210. As discussed, in some embodiments, the at least one solar cell 220 is directly above the first layer 210—that is, there is no intervening layer between the at least one solar cell 220 and the first layer 210. In some embodiments, at least one solar cell 220 is not directly above the first layer 210—that is, there is at least one layer intervening between the at least one solar cell 220 and the first layer 210. In some embodiments, there is at least two layers, at least three layers, or more than three layers intervening between the at least one solar cell 220 and the first layer 210. As discussed, in some embodiments the at least one solar cell 220 may include a plurality of solar cells 220. In some embodiments the at least one solar cell 220 may include a plurality of solar cells 220 adjacent one another. In some embodiments the at least one solar cell 220 may include a plurality of solar cells 220 in one or more rows. In some embodiments the at least one solar cell 220 may include a plurality of solar cells 220 in one row. In some embodiments the at least one solar cell 220 may include a plurality of solar cells 220 in more than one row.

As the drawings show, in some embodiments, the base portion 200 may include a base portion top edge 230, a base portion bottom edge 240, a base portion first side edge 250, and a base portion second side edge 260. The base portion bottom edge 240 may be opposite the base portion top edge 230, the base portion first side edge 250 may extend between the base portion top edge 230 and the base portion bottom edge 240, and the base portion second side edge 260 may extend between the base portion top edge 230 and the base portion bottom edge 240 as well as be opposite the base portion first side edge 250.

As discussed, in some embodiments, as the figures show, the base portion 200 may but need not, include a junction box 270.

As the drawings further show, in some embodiments, the headlap portion 300 may include a second layer 310. In some embodiments, the headlap portion 300 has a headlap portion top edge 330, a headlap portion bottom edge 340, a headlap portion first side edge 350, and a headlap portion second side edge 360. The headlap portion bottom edge 340 may be opposite the headlap portion top edge 330, the headlap portion first side edge 350 may extend between the headlap portion top edge 330 and the headlap portion bottom edge 340, and the headlap portion second side edge 360 may extend between the headlap portion top edge 330 and the headlap portion bottom edge 340, and may be opposite the headlap portion first side edge 350.

As discussed, in some embodiments, the base portion 200 and the headlap portion 300 may be connected to one another, thereby to form the photovoltaic module 100. Also as discussed, in some embodiments, an entire length of the base portion top edge 230 and an entire length of the headlap portion bottom edge 340 may be connected with each another. In some embodiments, less than the entire length of the base portion top edge 230 and/or less than the entire length of the headlap portion bottom edge 340 may be connected with each another.

As shown in FIG. 3, in some embodiments of the present invention, the headlap portion 300 may but need not, include one or more of the components 370 above the second layer 310. For example, FIG. 3 shows component 370 in the form of an electrical jumper assembly, including electrical wires within a jumper sleeve above the second layer 310. As discussed, in some embodiments, the electrical jumper assembly may be configured to electrically connect the at least one solar cell 220 with at least one solar cell of another photovoltaic module (not shown). Also as discussed, in some embodiments, the component 370, whether the electrical jumper assembly and/or jumper sleeve, or another component, may be directly above the second layer 310— that is, there may be no intervening layer between the component 370 and the second layer 310; while in other embodiments, the component 370 may not be directly above the second layer 310—that is, there is at least one layer, at least two layers, at least three layers, or more than three layers, intervening between the component 370 and the second layer 310.

In some embodiments, as discussed, the component 370 may include a controller, and the controller may be configured to control operation of the at least one solar cell, and/or of an electronic component other than the at least one solar cell. In some embodiments. In some embodiments, the component 370 may include a communications module, and the communications module may be configured to communicate data related to at least one of the at least one solar cell, and/or the roofing deck. In some embodiments, the component 370 may include a sensor, and the sensor may be configured to sense data related to at least one of the at least one solar cell, and/or the roofing deck.

As discussed, although not shown in the figures, either or both of the base portion 200 and/or the headlap portion 300 may include a fastener area.

As discussed, the base portion 200 may be connected to the headlap portion 300 by various methods, such as by welding, laminating, adhering, or fastening the portions to one another. In some embodiments, when the base portion 200 is welded to the headlap portion 300, a weld seam 400, as described, may be between the base portion 200 and the headlap portion 300.

FIG. 4 shows an example of the headlap portion 300 that is composed of a fire-resistant or retardant material, as discussed herein. Although the figure shows that headlap portion 300 omits any module or component, this headlap portion may include one or more of any or all of the components and/or modules discussed herein.

In some embodiments of the invention, one of more of the photovoltaic modules 100 may be installed above a roof deck, in a roofing system, as discussed. In some embodiments, one of more of the photovoltaic modules 100 may be installed above the roof deck with components other than the photovoltaic modules 100—for example, with one or more roofing shingles that do not include at least one solar cell. In some embodiments, one of more of the photovoltaic modules 100 may be installed directly on the roof deck—that is, with no intervening layer or component between the roof deck and the photovoltaic modules 100. In some embodiments, one of more of the photovoltaic modules 100 may be installed indirectly on the roof deck—that is, with at least one intervening layer or component, such as but not limited to a roofing underlayment, between the roof deck and the photovoltaic modules 100. In some embodiments, the present invention includes a method, in which one or more of the described components, such as the photovoltaic modules 100, and/or portions of the photovoltaic module 100 such as but not limited to the headlap portion 300 and/or the base portion 200 are obtained. In some embodiments, the invention includes a method of forming the photovoltaic module 100, as described herein. In some embodiments, the invention includes a method of installing the photovoltaic module 100, such as but not limited to on a roof deck, as described.

Variations, modifications and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. Thus, for example, in each instance herein, any of the terms “comprising,” “consisting essentially of” and “consisting of” may be replaced with either of the other two terms, without altering their respective meanings as defined herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

1. A photovoltaic module, comprising:
a base portion,
wherein the base portion comprises:
a first layer, and
at least one solar cell,
wherein the at least one solar cell is above the first layer,
wherein the first layer has an edge;
a headlap portion,
wherein the headlap portion comprises a second layer,
wherein the second layer has an edge,
wherein the headlap portion and the base portion are joined to one another along the edge of the first layer and the edge of the second layer.

2. The photovoltaic module of claim 1, wherein the at least one solar cell comprises a plurality of solar cells.

3. The photovoltaic module of claim 1, wherein the headlap portion further comprises at least one electrical jumper assembly,
wherein the at least one electrical jumper assembly is configured to electrically connect the photovoltaic module with another photovoltaic module.

4. The photovoltaic module of claim 1, wherein the headlap portion further comprises a controller,
wherein the controller is configured to control operation of the at least one solar cell.

5. The photovoltaic module of claim 1, wherein the headlap portion further comprises a communications module,
wherein the communications module is configured to communicate data related to at least one of:
the at least one solar cell, and
a roofing deck.

6. The photovoltaic module of claim 1, wherein the headlap portion further comprises a sensor,
wherein the sensor is configured to sense data related to at least one of:
the at least one solar cell, and
a roofing deck.

7. The photovoltaic module of claim 1, wherein the headlap portion comprises a fire-retardant material.

8. The photovoltaic module of claim 1, wherein the headlap portion further includes a fastener area,
wherein the fastener area is configured to receive a fastener to hold the photovoltaic module to a roofing deck.

9. The photovoltaic module of claim 1, further comprising a weld seam,
wherein the base portion connects with the headlap portion at the weld seam.

10. A kit, comprising:
a base portion,
wherein the base portion comprises:
a first layer, and
at least one solar cell,
wherein the at least one solar cell is above the first layer,
wherein the first layer has an edge;
a plurality of headlap portions,
wherein the plurality of headlap portions comprises at least a first headlap portion, and a second headlap portion,
wherein the first headlap portion comprises at least one electrical jumper assembly,
wherein the at least one electrical jumper assembly is configured to
electrically connect with another photovoltaic module,
wherein the second headlap portion comprises a controller,
wherein the controller is configured to control operation of the at least one solar cell,
wherein each of the first and second headlap portions comprises a second layer,
wherein each second layer has an edge,
wherein the edge of each second layer is configured to join to the edge of the first layer.

11. The kit of claim 10, wherein the at least one solar cell comprises a plurality of solar cells.

12. The kit of claim 10, wherein the at least one electrical jumper assembly is above the second layer of the first headlap portion.

13. The kit of claim 10, wherein the plurality of headlap portions comprises a third headlap portion,
wherein the third headlap portion comprises a communications module,
wherein the communications module is configured to communicate data related to at least one of:
the at least one solar cell, and
a roofing deck.

14. The kit of claim 10, wherein the plurality of headlap portions comprises a third headlap portion,
wherein the third headlap portion comprises a sensor,
wherein the sensor is configured to sense data related to at least one of:
the at least one solar cell, and
a roofing deck.

15. The kit of claim 10, wherein at least one of the first headlap portion and the second headlap portion comprises a fire-retardant material.

16. The kit of claim 10, wherein first headlap portion includes a fastener area,
wherein the fastener area is configured to receive a fastener to hold the first headlap portion to a roofing deck.

17. The kit of claim 10, wherein the edge of the first layer is configured to be laminated with the edges of the second layers.

18. The kit of claim 10, wherein the edge of the first layer is configured to be fastened with the edges of the second layers.

19. The kit of claim 10, wherein the edge of the first layer is configured to be welded with the edges of the second layers.

20. The kit of claim 10, wherein the edge of the first layer is configured to be adhered with the edges of the second layers.
